(19) United States
(12) Patent Application Publication
(10) Pub. No.: US 2024/0036486 A1
(43) Pub. Date: Feb. 1, 2024

(54) MANUFACTURING METHOD OF SEMICONDUCTOR APPARATUS

(71) Applicant: FUJI ELECTRIC CO., LTD., Kanagawa (JP)

(72) Inventors: Kazuhiro KITAHARA, Matsumoto-city (JP); Naoko KODAMA, Matsumoto-city (JP)

(21) Appl. No.: 18/337,028

(22) Filed: Jun. 18, 2023

(30) Foreign Application Priority Data
Jul. 27, 2022 (JP) 2022-119876

(51) Int. Cl. G03F 9/00

(52) U.S. Cl. CPC G03F 9/708; G03F 9/7088; G03F 9/7084

(57) ABSTRACT

Provided is a manufacturing method of a semiconductor apparatus including: detecting a position by detecting positional deviation of the upper surface mark and the lower surface mark, by acquiring an upper surface image obtained by observing the upper surface mark from above the upper surface of the semiconductor substrate and a lower surface image obtained by observing the lower surface mark through the semiconductor substrate from above the upper surface of the semiconductor substrate; and forming an element by forming a semiconductor element in the semiconductor substrate, where in a top view in which the upper surface mark and the lower surface mark are projected onto a plane parallel to the upper surface, one of the upper surface mark and the lower surface mark is larger than an other, and the one entirely covers the other.

The contents of the following patent application(s) are incorporated herein by reference:

NO. 2022-119876 filed in JP on Jul. 27, 2022.

### BACKGROUND

### 1. Technical Field

The present invention relates to a manufacturing method of a semiconductor apparatus.

### 2. Related Art

In a manufacturing process of a semiconductor apparatus, a technology is known to form a mark for detecting a position on a semiconductor substrate (see Patent Documents 1 and 2, for example).

Patent Document 1: Japanese Patent Application Publication No. 2012-253145.

Patent Document 2: Japanese Patent Application Publication No. 2019-120769.

### BRIEF DESCRIPTION OF THE DRAWINGS

FIG. 1 illustrates one example of a manufacturing method of a semiconductor apparatus according to one embodiment of the present invention.

FIG. 2 is a top view showing one example of a semiconductor substrate 10.

FIG. 3 is an enlarged view of a region A in FIG. 2.

FIG. 4 illustrates one example of a position detecting step S102.

FIG. 5 shows one example of an upper surface image 202 and a lower surface image 204 according to a reference example.

FIG. 6 shows one example of an upper surface image 206-1 and a lower surface image 208-1 according to a reference example.

FIG. 7 shows one example an upper surface image 206-2 and a lower surface image 208-2 according to a reference example.

FIG. 8 shows one example of an upper surface image 206-3 and a lower surface image 208-3 according to a reference example.

FIG. 9 is a cross-sectional view showing a configuration example of the semiconductor substrate 10 according to an embodiment example.

FIG. 10 shows one example of an upper surface image 212 and a lower surface image 214.

FIG. 11 shows one example of an upper surface image 216-1 and a lower surface image 218-1 according to an embodiment example.

FIG. 12 shows one example of an upper surface image 216-2 and a lower surface image 218-2.

FIG. 13 illustrates a shape example of an upper surface mark 30 and a lower surface mark 50 in a top view.

FIG. 14 is a table showing measurement results of mark positions for a plurality of samples in which shapes and sizes of an upper surface mark and a lower surface mark are changed.

FIG. 15 shows a film thickness of each member.

FIG. 16 shows another structural example of the lower surface mark 50.

FIG. 17 shows another structural example of the lower surface mark 50.

### DESCRIPTION OF EMBODIMENT EXAMPLES

Hereinafter, the present invention will be described through embodiments of the invention, but the following embodiments do not limit the invention according to claims. In addition, not all combinations of features described in the embodiments are essential to solutions of the invention. In the present specification and drawings, elements having substantially the same functions and configurations are denoted by the same reference numerals to omit duplicated description, and elements which are not directly correlated with the present invention are omitted from the drawings. In addition, in one drawing, elements having the same function and configuration are representatively denoted by a reference numeral, and the reference numerals for the others may be omitted.

In the present specification, one side in a direction parallel to a depth direction of a semiconductor substrate is referred to as “upper” and the other side is referred to as “lower”. One surface of two principal surfaces of a substrate, a layer or other members is referred to as an upper surface, and the other surface is referred to as a lower surface. The ‘upper’ and ‘lower’ directions are not limited to a gravity direction or a direction at a time of mounting a semiconductor module.

In the present specification, technical matters may be described using orthogonal coordinate axes of an X axis, a Y axis, and a Z axis. The orthogonal coordinate axes are merely for specifying relative positions of components, and not for limiting a specific direction. For example, the Z axis is not limited to indicate a height direction with respect to the ground. A +Z axis direction and a −Z axis direction are directions facing each other. When a direction is referred to as a “Z axis direction” without these “+” and “−” signs, it means that the direction is parallel to the +Z axis and the −Z axis. In the present specification, the orthogonal axes parallel to an upper surface and a lower surface of the semiconductor substrate are defined as the X axis and the Y axis. In addition, the axis perpendicular to the upper surface and the lower surface of the semiconductor substrate is defined as the Z axis. In the present specification, a direction of the Z axis may be referred to as a depth direction. In addition, in the present specification, a direction parallel to the upper surface and the lower surface of the semiconductor substrate, including the X axis and the Y axis, may be referred to as a horizontal direction.

In the present specification, a case where a term such as “same” or “equal” is mentioned may include a case where there is an error caused by a manufacturing variation or the like. That error is within 10%, for example.

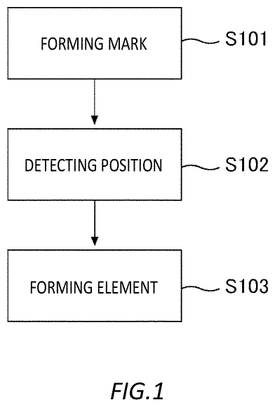

FIG. 1 illustrates one example of a manufacturing method of a semiconductor apparatus according to one embodiment of the present invention. FIG. 1 shows some manufacturing processes in the manufacturing method. The semiconductor apparatus includes a semiconductor element formed in a semiconductor substrate such as a silicon substrate. The semiconductor element is, for example, a power semiconductor element such as an Insulated Gate Bipolar Transistor (IGBT), but is not limited thereto.

The semiconductor element may have a structure on an upper surface side and a structure on a lower surface side of the semiconductor substrate. For example, an emitter region of a transistor element such as the IGBT and an anode region of a diode element such as a free wheel diode are formed on the lower surface side of the semiconductor substrate, and a collector region of the transistor element and a cathode region of the diode element are formed on the upper surface side of the semiconductor substrate. As one example, the semiconductor element is a vertical device in which a current flows between an upper surface and a lower surface of the semiconductor substrate. The semiconductor element may be a reverse conducting IGBT (RC-IGBT).

The manufacturing method in the present example includes a mark forming step S101, a position detecting step S102, and an element forming step S103. The mark forming step S101 forms an upper surface mark on the upper surface of the semiconductor substrate, and forms a lower surface mark on the lower surface of the semiconductor substrate. The semiconductor substrate in the present example is a disk-shaped semiconductor wafer. The upper surface and the lower surface of the semiconductor substrate are two principal surfaces arranged facing each other in the semiconductor substrate.

The upper surface mark and the lower surface mark may be a concave portion or a convex portion which is formed in a resist, an oxide film, a nitride film, or other films provided on the upper surface or the lower surface of the semiconductor substrate. The concave portion may or may not penetrate these films. The upper surface mark or the lower surface mark may be a concave portion or a convex portion of the semiconductor substrate itself, which is formed by removing part of the upper surface or the lower surface of the semiconductor substrate.

The position detecting step S102 acquires an image obtained by observing the upper surface mark and the lower surface mark, and detects positional deviation of the upper surface mark and the lower surface mark in a top view. The top view refers to observing each member from a direction perpendicular to the upper surface of the semiconductor substrate. In the top view, a position of each member may be observed for a case where each member is projected onto a plane parallel to the upper surface of the semiconductor substrate.

The element forming step S103 forms at least part of the structure of the semiconductor element in the semiconductor substrate. The element forming step S103 may form at least part of the structure of the semiconductor element by using a resist patterned according to a pattern of the structure to be formed. The element forming step S103 may, based on a resist pattern, implant impurities into the semiconductor substrate, etch the semiconductor substrate, form a dielectric film on the semiconductor substrate, or perform another processing.

The mark forming step S101 may form the upper surface mark or the lower surface mark in the resist formed on the upper surface or the lower surface of the semiconductor substrate. The mark forming step S101 may form the upper surface mark or the lower surface mark in the resist where an element pattern corresponding to the structure of the semiconductor element to be formed is formed. A relative position between the mark and the element pattern to be formed in the same resist is predetermined. Therefore, positional deviation between the element pattern on the upper surface and the element pattern on the lower surface can be detected by detecting the positional deviation of the upper surface mark and the lower surface mark. If an amount of the positional deviation has exceeded an allowable range, that resist may be removed, and a new resist may be applied. A mark and an element pattern may be formed in the new resist such that an amount of positional deviation between marks is small.

As one example, a gate structure and an n type emitter region of the transistor element as well as a p type anode region of the diode element are formed on the lower surface of the semiconductor substrate. A p type collector region of the transistor element and an n type cathode region of the diode element are formed on the upper surface of the semiconductor substrate. In the present example, each structure of the lower surface of the semiconductor substrate is formed, and then the collector region and the cathode region on the upper surface are formed. Each process shown in FIG. 1 is a process for forming the collector region and the cathode region, as one example. The mark forming step S101 patterns a structure of the upper surface mark as well as a structure of one of the collector region and the cathode region in the resist formed on the upper surface of the semiconductor substrate. The element forming step S103 forms one of the collector region and the cathode region by implanting the impurities with that resist being as a mask. Herein, positional deviation between the collector region and the cathode region to be formed by using that resist, and the structure on the lower surface side of the substrate can be detected by detecting the positional deviation between the upper surface mark and the lower surface mark in the position detecting step S102.

The manufacturing processes of the semiconductor apparatus are not limit to what is mentioned above. For example, the element forming step S103 may control, with a position of the upper surface mark being as a reference position, a position where the impurities are implanted into the upper surface of the semiconductor substrate, or may control, with a position of the lower surface mark being as a reference position, a position where the impurities are implanted into the lower surface of the semiconductor substrate. In this case, the element forming step S103 may adjust, based on the positional deviation of the upper surface mark and the lower surface mark detected in the position detecting step S102, a position of a structure to be formed with the upper surface mark being as a reference and a position of a structure to be formed with the lower surface mark being as a reference. In any of the manufacturing processes, since detection accuracy of the positional deviation of the upper surface mark and the lower surface mark affects the positional deviation between the structure of the upper surface and the structure of the lower surface of the semiconductor element, it is preferable that the positional deviation can be accurately detected in the position detecting step S102.

In the manufacturing method, the mark forming step S101, the position detecting step S102, and the element forming step S103 may be repeated for each structure of the semiconductor element. For example, if a first structure and a second structure having different positions or shapes are formed, the mark forming step S101, the position detecting step S102, and the element forming step S103 may be performed in each of cases where the first structure is formed and where the second structure is formed.

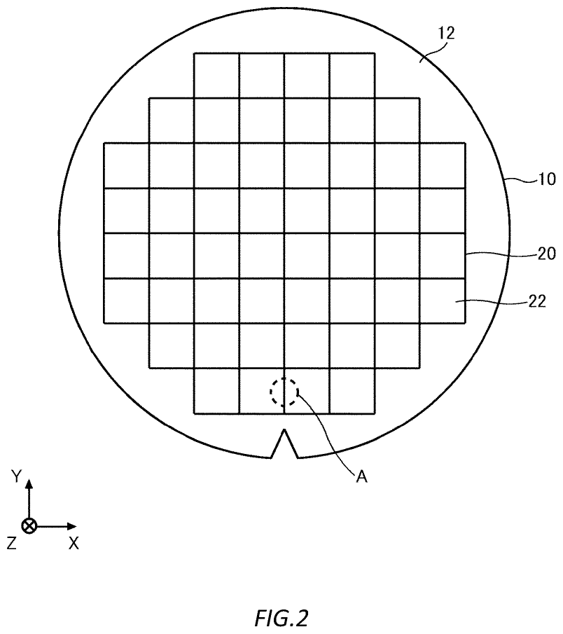

FIG. 2 is a top view showing one example of a semiconductor substrate 10. A plurality of semiconductor chips 22 may be formed on the semiconductor substrate 10. The semiconductor chip 22 is one example of a semiconductor apparatus. Each semiconductor chip 22 can be cut out by cutting the semiconductor substrate 10 along a scribe line 20 on an upper surface 12 of the semiconductor substrate 10. In the present specification, two orthogonal axes parallel to the upper surface 12 of the semiconductor substrate 10 are defined as an X axis and a Y axis, and an axis orthogonal to the upper surface 12 is defined as a Z axis. The scribe line 20 may have a portion parallel to the X axis and a portion parallel to the Y axis.

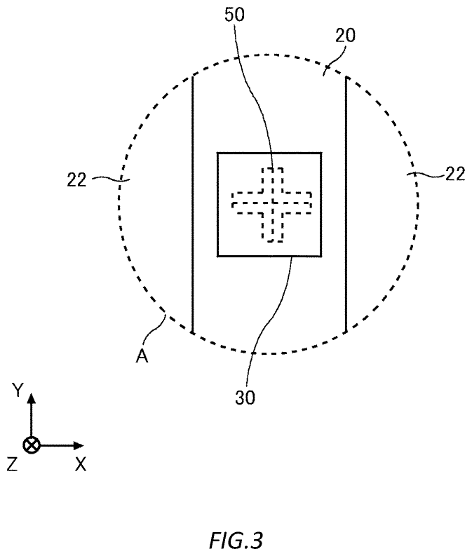

FIG. 3 is an enlarged view of a region A in FIG. 2. The region A includes the scribe line 20 and two semiconductor chips 22 separated by the scribe line 20. In the mark forming step S101, an upper surface mark 30 may be formed in the scribe line 20 on the upper surface 12 of the semiconductor substrate 10. In addition, a lower surface mark 50 may be formed at a position overlapping with the upper surface mark 30 on the lower surface of the semiconductor substrate 10. In FIG. 3, the lower surface mark 50 is indicated by a dashed line.

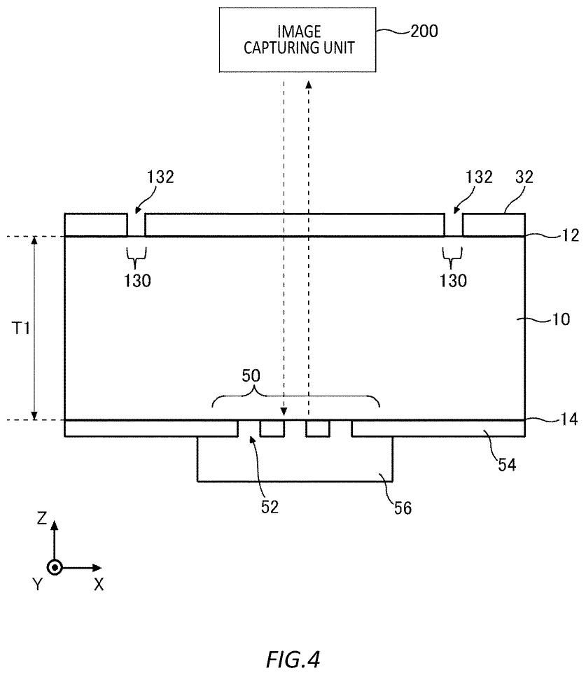

FIG. 4 illustrates one example of the position detecting step S102. In the present example, an upper surface mark 130 is formed instead of the upper surface mark 30 described in FIG. 3. The upper surface mark 130 in the present example is formed in a resist 32. The resist 32 is applied on the upper surface 12 of the semiconductor substrate 10. The upper surface mark 130 in the present example is a groove portion 132 formed in the resist 32. As mentioned above, the resist 32 may be provided with a pattern for forming a semiconductor element in addition to a pattern of the upper surface mark 130. The resist 32 may be formed on both the scribe line 20 and the semiconductor chip 22.

The lower surface mark 50 in the present example is form in a film 54. The film 54 is form on a lower surface 14 of the semiconductor substrate 10. The film 54 may be an insulating film such as an oxide film, a nitride film, or a resist. The lower surface mark 50 in the present example has a groove portion 52 formed in the film 54. The film 54 may also be formed on the semiconductor chip 22 as part of a structure of the semiconductor element. For example, the film 54 may also be formed on the semiconductor chip 22 as a dielectric film of the semiconductor element. The groove portion 52 may be provided in the semiconductor substrate 10 itself.

The mark forming step S101 may form a cover portion 56 for covering the lower surface mark 50. The cover portion 56 is formed of a material having a reflectance rate higher than the lower surface mark 50 (the film 54, in the present example). For example, the cover portion 56 is formed of a metal material such as aluminum. Providing the cover portion 56 can increase difference between a reflectance rate of an irradiation light in the groove portion 52 of the lower surface mark 50 and a reflectance rate of the irradiation light in a portion other than the groove portion 52. Therefore, it is possible to increase contrast between the groove portion 52 and another portion in an image obtained by capturing the lower surface mark 50.

The position detecting step S102 acquires an upper surface image obtained by observing the upper surface mark 130 from above the upper surface 12 of the semiconductor substrate 10, and a lower surface image obtained by observing the lower surface mark 50 through the semiconductor substrate 10 from above the upper surface 12 of the semiconductor substrate 10. In the example of FIG. 4, the upper surface image and the lower surface image are acquired by an image capturing unit 200 arranged above the upper surface 12.

The image capturing unit 200 has an image capturing element, a light source for generating an irradiation light to be irradiated to the semiconductor substrate 10, and an optical system for passing the irradiation light toward the semiconductor substrate 10 and passing a reflective light from the semiconductor substrate 10 toward the image capturing element. The optical system may include an adjustment unit for adjusting a focal position of the image capturing element.

The image capturing unit 200 may irradiate the irradiation light with the same wavelength in a case where the upper surface image is acquired and in a case where the lower surface image is acquired. The irradiation light includes a wavelength component capable of transmitting through the semiconductor substrate 10. The irradiation light includes a wavelength component of an infrared light, as one example.

When acquiring the upper surface image, the image capturing unit 200 may focus on a position of the upper surface 12 of the semiconductor substrate 10. When acquiring the upper surface image, the image capturing unit 200 receives a reflective light from the upper surface mark 130. However, since the image capturing unit 200 also receives a light which has transmitted through the semiconductor substrate 10 and has been reflected in the lower surface mark 50, the lower surface mark 50 may be reflected in the upper surface image in addition to the upper surface mark 130.

When acquiring the lower surface image, the image capturing unit 200 may focus on a position of the lower surface 14 of the semiconductor substrate 10. When acquiring the lower surface image, the image capturing unit 200 receives a reflective light which has transmitted through the semiconductor substrate 10 and has been reflected in the lower surface mark 50. However, since the image capturing unit 200 also receives a light reflected in the upper surface mark 130, the upper surface mark 130 may be reflected in the lower surface image in addition to the lower surface mark 50.

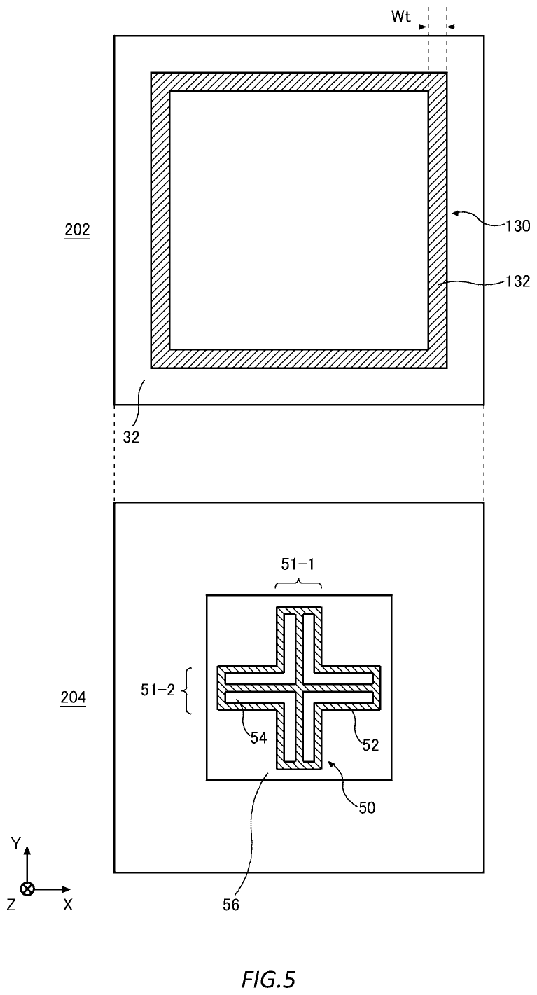

FIG. 5 shows one example of an upper surface image 202 and a lower surface image 204 according to a reference example. The upper surface image 202 and the lower surface image 204 shown in FIG. 5 are images of the same region in a top view. The upper surface image 202 includes the upper surface mark 130, and the lower surface image 204 includes the lower surface mark 50. As mentioned above, the upper surface image 202 may include the lower surface mark 50, which is omitted from the upper surface image 202 in FIG. 5. In addition, the lower surface image 204 may include the upper surface mark 130, which is omitted from the lower surface image 204 in FIG. 5.

The upper surface mark 130 in the present example has the groove portion 132 arranged around the lower surface mark 50 in the top view. The groove portion 132 in the present example encloses the lower surface mark 50 in the top view. A minimum width of the groove portion 132 in the top view is defined as Wt. The width Wt may be smaller than 20 μm.

The lower surface mark 50 in the present example has the groove portion 52. A width of the groove portion 52 in the top view may be 10 μm or less, or may be 5 μm or less. The groove portion 52 may have two or more straight portions 51 crossing in the top view. In the example of FIG. 5, the groove portion 52 has one or more straight portions 51-1 extending in a Y axis direction and one or more straight portions 51-2 extending in an X axis direction. The straight portion 51-1 and the straight portion 51-2 in the present example cross each other at their central portions. A plurality of straight portions 51-1 may be arranged side by side in the X axis direction. The film 54 remains between the straight portions 51-1. A plurality of straight portion 51-2 may be arranged side by side in the Y axis direction. The film 54 remains between the straight portions 51-2.

The lower surface image 204 may include the cover portion 56. The cover portion 56 is larger than the lower surface mark 50 in the top view. The cover portion 56 entirely covers the lower surface mark 50.

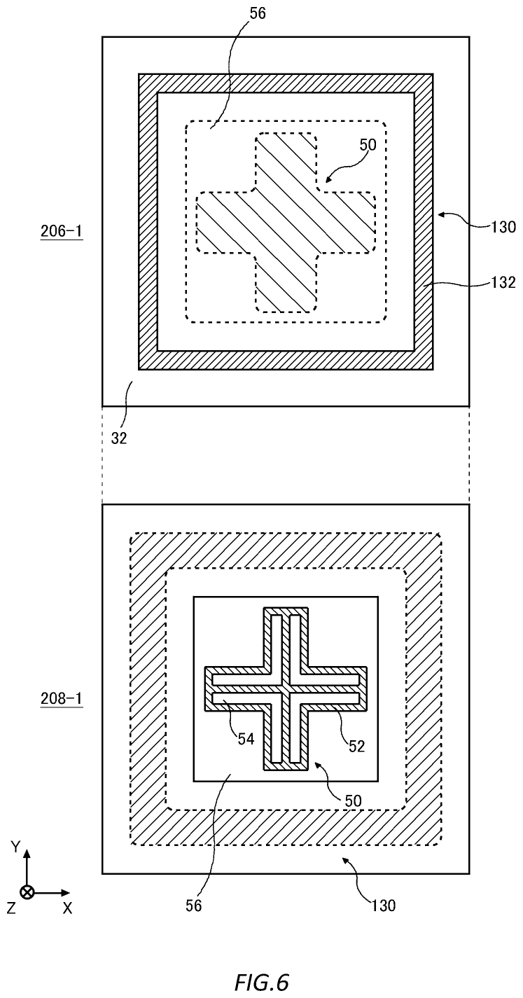

FIG. 6 shows one example of an upper surface image 206-1 and a lower surface image 208-1 according to a reference example. As mentioned above, the upper surface image 206-1 includes an image of the upper surface mark 130, and the lower surface image 208-1 includes an image of the lower surface mark 50.

The upper surface image 206-1 in the present example further includes images of the lower surface mark 50 and the cover portion 56. In FIG. 6, the lower surface mark 50 and the cover portion 56 reflected in the upper surface image 206-1 are indicated by dashed lines. Since the lower surface mark 50 and the cover portion 56 are arranged apart from a focal position when the upper surface image 206-1 is captured, the images of the lower surface mark 50 and the cover portion 56 in the upper surface image 206-1 are broader than actual sizes of the structural objects and are indistinctly observed. How the images of the lower surface mark 50 and the cover portion 56 broaden changes depending on a thickness T1 (see FIG. 4) of the semiconductor substrate 10. In addition, since a reflective light from the lower surface mark 50 and the cover portion 56 passes through the semiconductor substrate 10, it is attenuated. Therefore, intensity of the images of the lower surface mark 50 and the cover portion 56 changes depending on the thickness T1 of the semiconductor substrate 10. The thickness T1 of the semiconductor substrate 10 in the present example is 60 μm.

The lower surface image 208-1 in the present example further includes the image of the upper surface mark 130. In FIG. 6, the upper surface mark 130 reflected in the lower surface image 208-1 is indicated by a dashed line. Since the upper surface mark 130 is arranged apart from a focal position when the lower surface image 208-1 is captured, the image of the upper surface mark 130 in the lower surface image 208-1 is broader than an actual size of the structural object and is indistinctly observed. How the image of the upper surface mark 130 broadens changes depending on the thickness T1 of the semiconductor substrate 10. Since a reflective light from the upper surface mark 130 does not pass through the semiconductor substrate 10, the image of the upper surface mark 130 in the lower surface image 208-1 may be observed more distinctly than the image of the lower surface mark 50 or the like in the upper surface image 206-1.

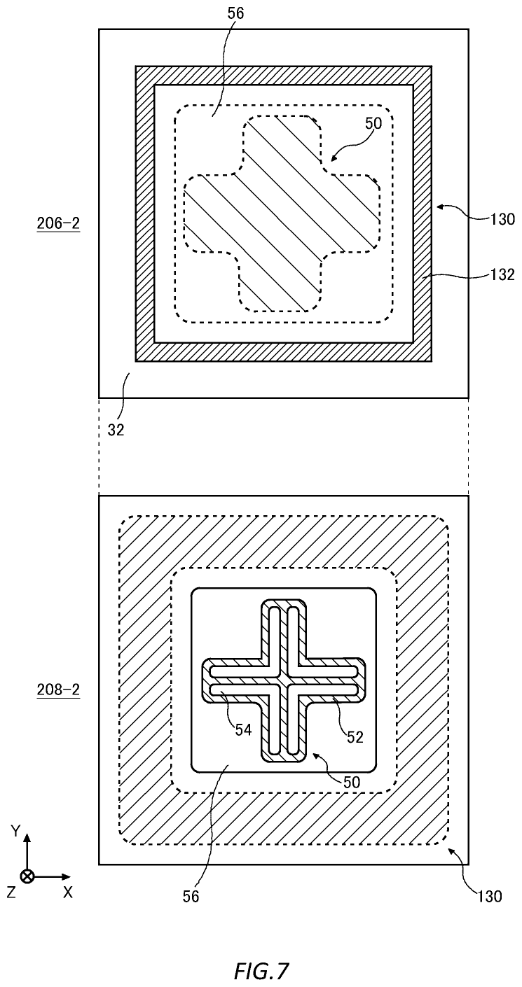

FIG. 7 shows one example an upper surface image 206-2 and a lower surface image 208-2 according to a reference example. In the present example, the upper surface image 206 and the lower surface image 208 are captured under the same condition as in FIG. 6 except that the thickness T1 of the semiconductor substrate 10 is 120 μm. As mentioned above, if the thickness T1 of the semiconductor substrate 10 increases, an image of the lower surface mark 50 or the like in the upper surface image 206-2 further broadens, and an image of the upper surface mark 130 in the lower surface image 208-2 further broadens.

In each image (the lower surface image 208-2, for example), if an image of a mark to be observed (the lower surface mark 50, for example) overlaps with an image of a mark (the upper surface mark 130, for example) that has been reflected, a position of the mark to be observed can no longer be accurately observed. In particular, if edge positions of the images of the marks are close to each other, an edge of the mark to be observed can no longer be observed accurately, and position detection accuracy of the mark to be observed deteriorates. If the upper surface mark 130 is formed of the groove portion 132 as in the present example, the groove portion 132 has two edges (two side walls constituting the groove portion 132 in the resist 32) close to each other. Therefore, if the image of the upper surface mark 130 is indistinct and the groove portion 132 overlaps with the lower surface mark 50, images of the two edges of the groove portion 132 strongly interfere with the image of the lower surface mark 50, and the image of the lower surface mark 50 can no longer be accurately detected. This also applies to the upper surface image 206-2. Note, however, that, as mentioned above, in the upper surface image 206-2, intensity of the image of the lower surface mark 50 or the like not to be observed is attenuated depending on the thickness T1 of the semiconductor substrate 10. On the other hand, in the lower surface image 208-2, intensity of the image of the lower surface mark 50 or the like to be observed is attenuated depending on the thickness T1 of the semiconductor substrate 10. Therefore, it is often the case that the interference between the mark images mentioned above occurs in the lower surface image 208-2.

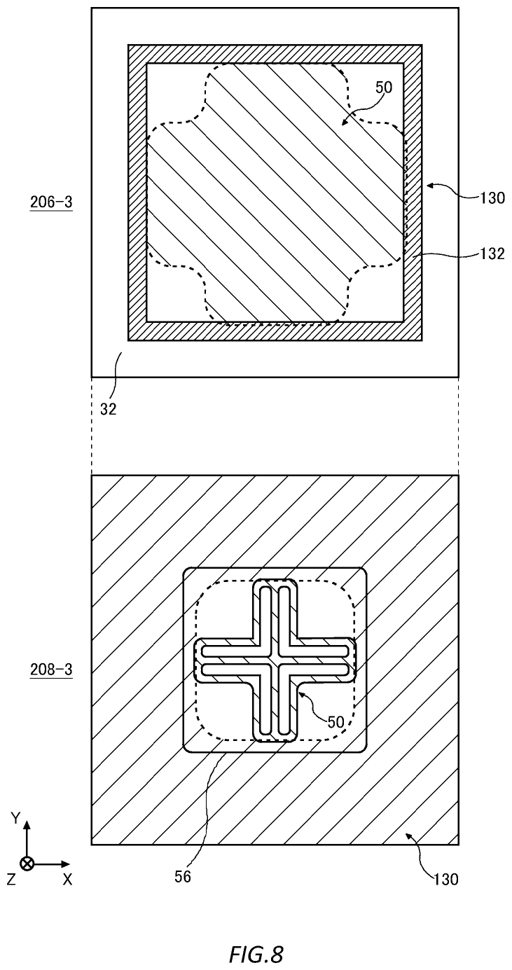

FIG. 8 shows one example of an upper surface image 206-3 and a lower surface image 208-3 according to a reference example. In the present example, the upper surface image 206 and the lower surface image 208 are captured under the same condition as in FIG. 6 except that the thickness T1 of the semiconductor substrate 10 is 180 μm. As mentioned above, if the thickness T1 of the semiconductor substrate 10 increases, an image of the lower surface mark 50 or the like in the upper surface image 206-2 further broadens, and an image of the upper surface mark 130 in the lower surface image 208-2 further broadens. In addition, in the lower surface image 208-2, since the intensity of the image of the lower surface mark 50 or the like to be observed is attenuated depending on the thickness T1 of the semiconductor substrate 10, it is even more difficult to observe the lower surface mark 50. In the present example, as shown in FIG. 6, if the thickness T1 of the semiconductor substrate 10 was 60 μm, a position of each mark could be accurately detected, but in the examples where the thickness T1 was 120 μm and where the thickness T1 was 180 μm, the lower surface mark 50 could not be detected depending on image processing by a computer on the lower surface image 208.

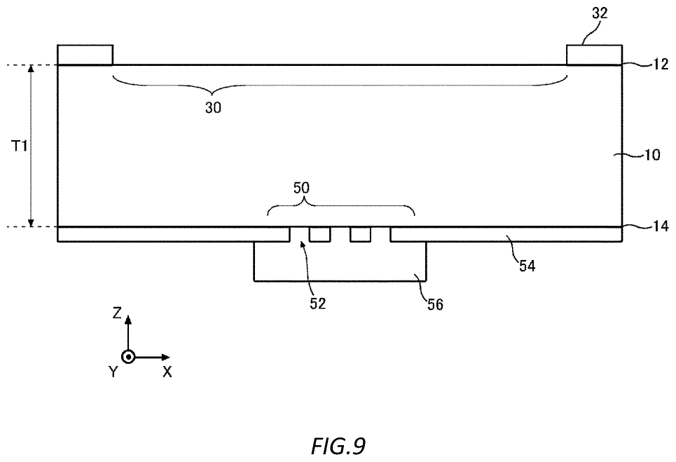

FIG. 9 is a cross-sectional view showing a configuration example of the semiconductor substrate 10 according to an embodiment example. The semiconductor substrate 10 in the present example is provided with the upper surface mark 30 instead of the upper surface mark 130 shown in FIG. 4 to FIG. 8. Other structures are similar to those in the examples described in FIG. 4 to FIG. 8. The upper surface mark 30 in the present example is a concave portion provided in the resist 32.

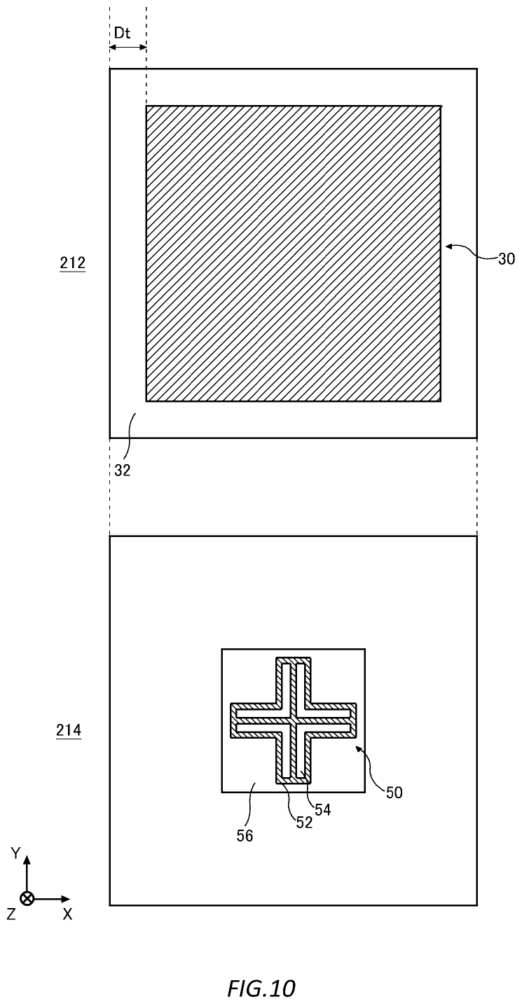

FIG. 10 shows one example of an upper surface image 212 and a lower surface image 214. The upper surface image 212 and the lower surface image 214 shown in FIG. 10 are images of the same region in a top view. The upper surface image 212 includes the upper surface mark 30, and the lower surface image 214 includes the lower surface mark 50. As mentioned above, the upper surface image 212 may include the lower surface mark 50, which is omitted from the upper surface image 212 in FIG. 10. In addition, the lower surface image 214 may include the upper surface mark 30, which is omitted from the lower surface image 214 in FIG. 10.

In a top view, one of the upper surface mark 30 and the lower surface mark 50 is larger than the other, and that one mark entirely covers that other mark. In the examples of FIG. 9 and FIG. 10, the upper surface mark 30 is larger than the lower surface mark 50, and the upper surface mark 30 entirely covers the lower surface mark 50. In another example, structures of the upper surface mark 30 and the lower surface mark 50 may be reversed. In other words, the lower surface mark 50 may be larger than the upper surface mark 30, and the lower surface mark 50 may entirely cover the upper surface mark 30.

The upper surface mark 30 in the present example is a concave portion arranged in the upper surface 12 of the semiconductor substrate 10. For example, the concave portion is a space formed by partially removing the resist 32. The concave portion of the upper surface mark 30 entirely covers the lower surface mark 50 in the top view. The upper surface mark 30 may be a convex portion arranged on the upper surface 12 of the semiconductor substrate 10. For example, the convex portion is the resist 32 remaining after removing the resist 32 other than the upper surface mark 30. Also in this case, the convex portion of the upper surface mark 30 entirely covers the lower surface mark 50 in the top view. In this manner, mutual interference between mark images in the upper surface image 212 and the lower surface image 214 can be reduced by forming the entire upper surface mark 30 as a concave portion or a convex portion so as to cover the lower surface mark 50. In other words, since the upper surface mark 30 is a uniform concave portion or convex portion, it has fewer edges than the upper surface mark 130 having the groove portion 132 shown in FIG. 5 or the like. Therefore, the interference between the mark images can be reduced.

It is preferable that, in the top view, the upper surface 12 of the semiconductor substrate 10 is provided with no concave or convex over a predetermined distance Dt from an end portion of the concave portion or the convex portion of the upper surface mark 30 covering the lower surface mark 50 toward an outside of the upper surface mark 30. That distance Dt may be 20 μm or more, may be 30 μm or more, may be 40 μm or more, or may by 50 μm or more.

As shown in FIG. 10, if the upper surface mark 30 is a concave portion provided in the resist 32, the resist 32 is provided over a range of a distance equal to or longer than the distance Dt from an end portion of the upper surface mark 30. The resist 32 may be continuously provided without any concave or convex, from the end portion of the upper surface mark 30 to an end portion of the scribe line 20. If the upper surface mark 30 is a concave portion, it is possible to suppress attenuation of an irradiation light for a case where the lower surface image 214 is captured. Therefore, in the lower surface image 214 in which the mark images are likely to interfere with each other, the lower surface mark 50 can be more accurately observed.

If the upper surface mark 30 is the remaining resist 32, the resist 32 is not provided over the range of the distance equal to or longer than the distance Dt from the end portion of the upper surface mark 30. The resist 32 may not be arranged from the end portion of the upper surface mark 30 to the end portion of the scribe line 20.

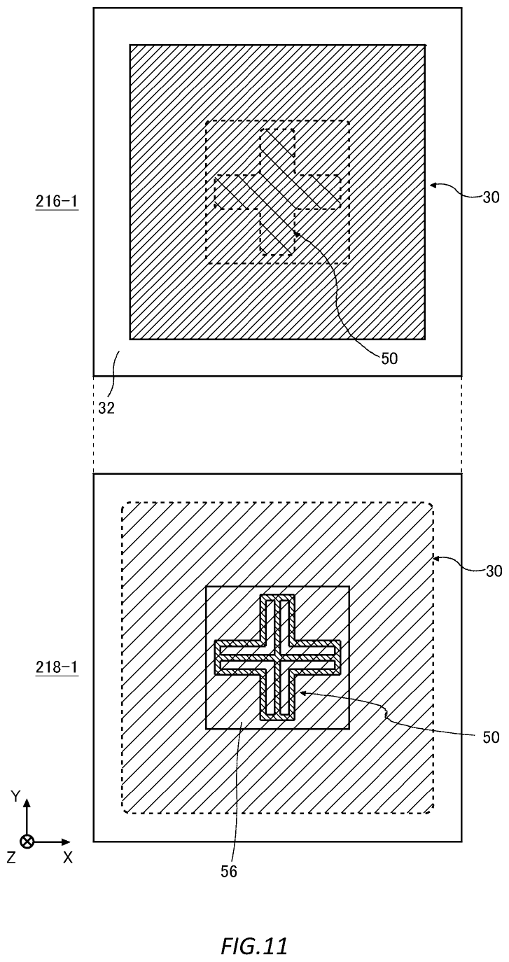

FIG. 11 shows one example of an upper surface image 216-1 and a lower surface image 218-1 according to an embodiment example. The thickness T1 of the semiconductor substrate 10 in the present example is 60 μm. As mentioned above, the upper surface image 216-1 includes an image of the upper surface mark 30, and the lower surface image 218-1 includes an image of the lower surface mark 50.

The upper surface image 216-1 in the present example further includes images of the lower surface mark 50 and the cover portion 56. The lower surface image 218-1 in the present example further includes an image of the upper surface mark 130. In the lower surface image 218-1, the image of the lower surface mark 50 overlaps with the image of the upper surface mark 30 that has been reflected, but since the image of the upper surface mark 30 is a substantially uniform image entirely covering the lower surface mark 50, an edge of the image of the lower surface mark 50 is less affected. Therefore, a position of the lower surface mark 50 can be accurately detected.

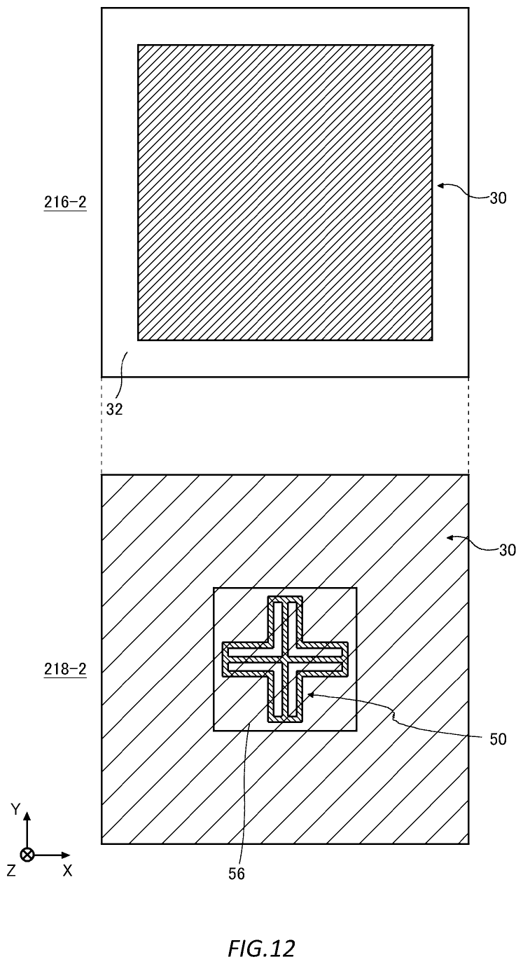

FIG. 12 shows one example of an upper surface image 216-2 and a lower surface image 218-2. In the present example, the upper surface image 216 and the lower surface image 218 are captured under the same condition as in FIG. 11 except that the thickness T1 of the semiconductor substrate 10 is 380 μm. As mentioned above, if the thickness T1 of the semiconductor substrate 10 increases, intensity of an image of the lower surface mark 50 or the like in the upper surface image 216-2 is attenuated. In the present example, little reflection of the lower surface mark 50 into the upper surface image 216-2 was observed.

If the thickness T1 of the semiconductor substrate 10 increases, an image of the upper surface mark 30 in the lower surface image 208-2 further broadens. However, since the image of the upper surface mark 30 is a substantially uniform image entirely covering the lower surface mark 50, an edge of the image of the lower surface mark 50 is less affected. In the present example, even if the thickness T1 of the semiconductor substrate 10 was set to 380 μm, the lower surface mark 50 could be accurately detected through image processing by a computer. Similarly, when the thickness T1 of the semiconductor substrate 10 was 120 μm or 180 μm, the lower surface mark 50 could be accurately detected. According to the present example, even if the thickness T1 of the semiconductor substrate 10 is increased, a position of the lower surface mark 50 can be accurately detected, and so the semiconductor apparatus can be accurately manufactured.

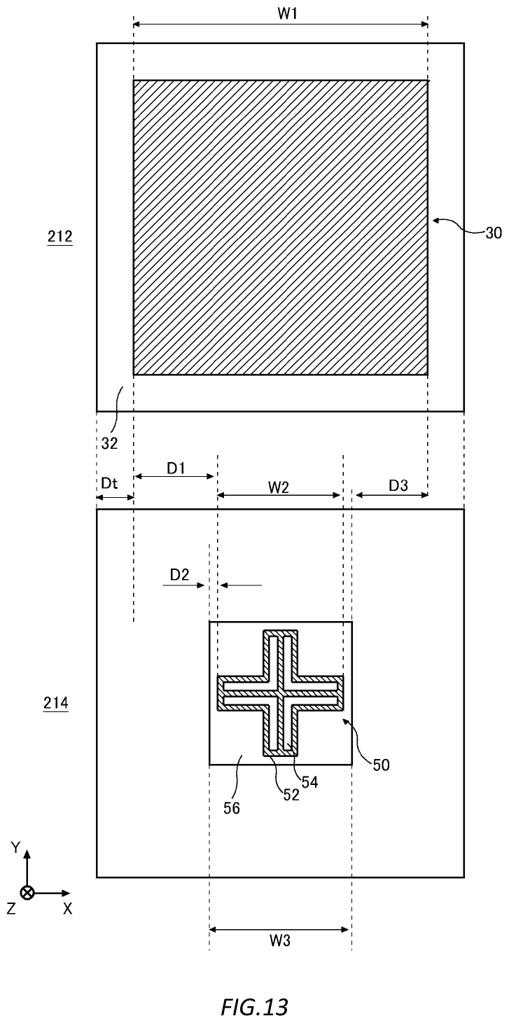

FIG. 13 illustrates a shape example of an upper surface mark 30 and a lower surface mark 50 in a top view. FIG. 13 shows the upper surface mark 30 of the upper surface image 212 and the lower surface mark 50 of the lower surface image 214. Since each mark is provided at a focal position, a size of the mark in each image indicates an actual size of the mark.

The upper surface mark 30 in the present example is larger than the lower surface mark 50. Setting the lower surface mark 50 smaller can set the cover portion 56 smaller. A width of the upper surface mark 30 in an X axis direction is defined as W1, and a width of the lower surface mark 50 in the X axis direction is defined as W2. As one example, the X axis direction is a direction perpendicular to an extending direction of the scribe line 20 provided with these marks. The width W1 in the present example is larger than the width W2. The width W1 may be larger than the width W2 by 40 μm or more, may be larger than the width W2 by 50 μm or more, or may be larger than the width W2 by 60 μm or more. The width W1 is smaller than a width of the scribe line 20 in the X axis direction. Increasing the width W1 can increase a distance D1 between an end portion of the upper surface mark 30 and an end portion of the lower surface mark 50 in a top view, and can suppress interference between edges of the marks in the images. The distance D1 may be 20 μm or more, may be 25 μm or more, or may be 30 μm or more. Since a mark not to be observed is broader in each image as the thickness T1 of the semiconductor substrate 10 is larger, the distance D1 may be determined according to the thickness T1. For example, the distance D1 may be 30% or more, may be 40% or more, or may be 50% or more, of the thickness T1. The distance D1 may be equal to or less than the thickness T1. In another example, the lower surface mark 50 may be larger than the upper surface mark 30 in the top view. The lower surface mark 50 and the upper surface mark 30 described in FIG. 13 may be respectively used as an upper surface mark and a lower surface mark.

In the top view, the cover portion 56 is larger than the lower surface mark 50 and is smaller than the upper surface mark 30. Since the cover portion 56 only needs to cover the lower surface mark 50, it only needs to be slightly larger than the lower surface mark 50. In the top view, a distance D2 between an end portion of the cover portion 56 and the end portion of the lower surface mark 50 may be smaller than a distance D3 between the end portion of the cover portion 56 and the end portion of the upper surface mark 30. The distance D2 may be half or less, may be ¼ or less, or may be 1/10 or less, of the distance D3. The distance D2 may be 5 μm or less. Note, however, that, if the distance between the end portions of the cover portion 56 and the lower surface mark 50 is too small, it may be more difficult to observe a position of the end portion of the lower surface mark 50. The distance D2 may be 1 μm or more, or may be 3 μm or more. The distance D3 may be 20 μm or more, may be 30 μm or more, or may be 40 μm or more.

It is preferable that, in the top view, a shape of the cover portion 56 is neither the same as nor similar to a shape of the lower surface mark 50. This facilitates distinction between the cover portion 56 and the lower surface mark 50. The cover portion 56 in the present example is a rectangle in the top view.

As one example, the width W1 of the upper surface mark 30 is 80 μm or more. The width W1 is smaller than the width of the scribe line 20. The width W1 may be 100 μm or less. The width W2 of the lower surface mark 50 is 20 μm or more and 40 μm or less. A width W3 of the cover portion 56 is 40 μm or more and 60 μm or less.

It is preferable that the upper surface mark 30 and the lower surface mark 50 do not have the same or similar shape in the top view. This can suppress interference between edges of mark images. The upper surface mark 30 in the present example is a rectangle having four sides. The lower surface mark 50 in the present example has a shape obtained by crossing two rectangular shapes. Since the lower surface mark 50 has the two crossing rectangular shapes, it has more sides than the upper surface mark 30. As mentioned above, intensity of an image of the upper surface mark 30 in the lower surface image 214 or the like is relatively high and is likely to interfere with an image of the lower surface mark 50. Therefore, forming the upper surface mark 30 into a simple shape such as a rectangle having a small number of sides (edges) can suppress interference of the image of the upper surface mark 30 in the lower surface image 214 or the like.

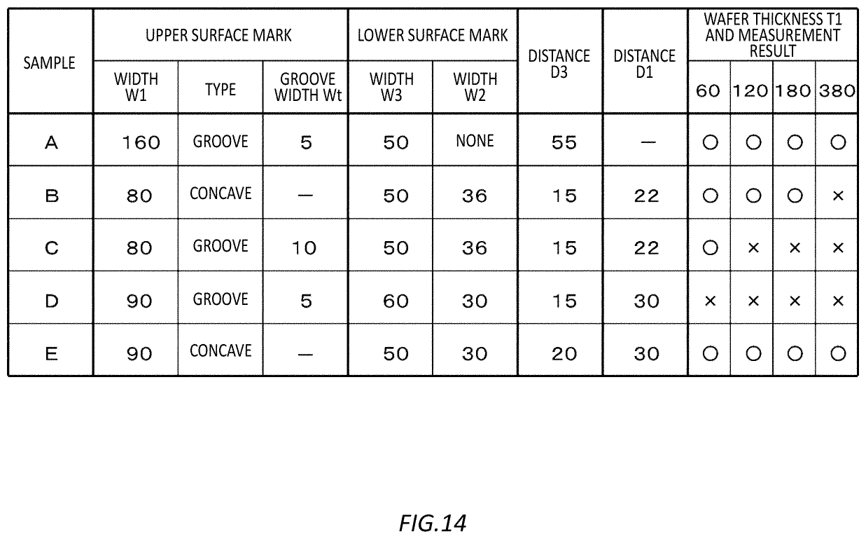

FIG. 14 is a table showing measurement results of mark positions for a plurality of samples in which shapes and sizes of an upper surface mark and a lower surface mark are changed. A unit of numerical values in the table shown in FIG. 14 is μm. In FIG. 14, circle marks indicate measurement results for a case where a position of an upper surface mark could be detected in an upper surface image and where a position of a lower surface mark could be detected in a lower surface image.

A sample A has the upper surface mark 130 shown in FIG. 5. The width W1 of the upper surface mark 130 is 160 μm, and the width Wt of the groove portion 132 is 5 μm. The width W1 of the upper surface mark 130 is a width of a region enclosed by the groove portion 132 of the upper surface mark 130. In addition, in the sample A, the cover portion 56 is provided, and the lower surface mark 50 is not provided. For the sample A, the cover portion 56 is used as the lower surface mark. For the sample A, the circle marks indicate measurement results for a case where the cover portion 56 could be detected in the lower surface image and where the upper surface mark 130 could be detected in the upper surface image.

In the sample A, since the upper surface mark 130 has the groove portion 132 which is narrow, interference in the lower surface image is relatively large. Furthermore, the cover portion 56 having a shape similar to that of the upper surface mark 130 is used as the lower surface mark. Therefore, an image of the cover portion 56 in the lower surface image is likely to interfere with an image of the upper surface mark 130 that has been reflected. In the sample A, when the width W1 of the upper surface mark 130 was increased to 160 μm and the distance D3 between the upper surface mark 130 and the cover portion 56 was increased to 55 μm, each mark could be detected when the thickness T1 of the semiconductor substrate 10 was in a range of 60 μm to 380 μm. However, setting the width W1 smaller than 160 μm and setting the distance D3 smaller than 55 μm makes it difficult to detect each mark.

A sample B has the upper surface mark 30 shown in FIG. 10. The width W1 of the upper surface mark 30 is 80 μm, the width W2 of the lower surface mark 50 is 36 μm, and the distance D1 between the upper surface mark 30 and the lower surface mark 50 is 22 μm. In the present example, since the upper surface mark 30 is a uniform concave portion, interference with the lower surface image is relatively small. Therefore, each mark can be detected more easily than in the sample A. When the distance D1 was approximately 20 μm or more, each mark could be detected even if the thickness T1 of the semiconductor substrate 10 was increased to 180 μm. However, if the thickness T1 of the semiconductor substrate 10 is larger than 380 μm, it may be difficult to detect each mark.

A sample E has the upper surface mark 30 shown in FIG. 10. The width W1 of the upper surface mark 30 is 90 μm, the width W2 of the lower surface mark 50 is 30 μm, and the distance D1 between the upper surface mark 30 and the lower surface mark 50 is 30 μm. In the present example, the distance D1 is increased by setting the upper surface mark 30 larger and setting the lower surface mark 50 smaller than in the sample B. In the present example, even if the thickness T1 of the semiconductor substrate 10 was increased to 380 μm, each mark could be detected. The distance D1 may be 30 μm or more. Alternatively, the distance D1 may be 7% or more, may be 8% or more, or may be 10% or more, of the thickness T1 of the semiconductor substrate 10.

Samples C and D each has the upper surface mark 130 shown in FIG. 5. Note, however, that the width Wt of the groove portion 132 of the sample C is 10 μm, and the width Wt of the groove portion 132 of the sample D is 5 μm. The distance D1 of the sample C is 22 μm, and the distance D1 of the sample D is 30 μm. Since the distance D1 of the sample C is smaller than the distance D1 of the sample D, it can be considered that images between marks are more likely to interfere with each other in the sample C. However, when the substrate thickness T1 was 60 μm, the lower surface mark could be detected in the sample C, but the lower surface mark could not be detected in the sample D. It is considered to be because the width Wt of the groove portion 132 of the sample C was large and the interference was suppressed. The distance Dt shown in FIG. 10 may be 20 μm or more.

The samples D and E has the same distance D1. However, each mark could not be detected at any substrate thickness T1 in the sample D, whereas each mark could be detected at any substrate thickness T1 in the sample E. Therefore, it can be learned that each mark is detected more easily by using the upper surface mark 30 described in FIG. 9 to FIG. 13 than by using the upper surface mark 130 described in FIG. 4 to FIG. 8. In addition, in the samples B and E, the upper surface mark 30 can be set smaller than in the sample A. For example, in the samples B and E, each mark can be easily set smaller than the scribe line 20. Therefore, each mark can be arranged at multiple positions on the semiconductor substrate 10. A plurality of sets of the upper surface mark 30 and the lower surface mark 50 may be arranged on the semiconductor substrate 10.

In addition, in the present example, the upper surface mark 30 and the lower surface mark 50 are both observed from an upper surface of the semiconductor substrate 10. If the upper surface mark 30 and the lower surface mark 50 are respectively observed from the upper surface and a lower surface of the semiconductor substrate 10, a stage on which the semiconductor substrate 10 is placed must be provided with an observation hole for observing the lower surface mark 50. If the semiconductor substrate 10 is warped due to a manufacturing process, since providing the observation hole in the stage cannot suck the semiconductor substrate 10 onto the stage at a portion provided with the observation hole, the semiconductor substrate 10 might be warped on the stage to aggravate measurement accuracy. In addition, a position where the mark is arranged will also be limited to a position of that observation hole. In the present example, since it is not necessary to provide the observation hole in the stage, the aggravation in the measurement accuracy can be reduced by firmly sucking the semiconductor substrate 10 onto the stage and flattening it. In addition, the upper surface mark 30 and the lower surface mark 50 can be arranged at multiple positions. Therefore, even if the semiconductor substrate 10 is warped, positional deviation between the marks can be detected. In addition, the positional deviation between the marks can be detected at any position on the semiconductor substrate 10.

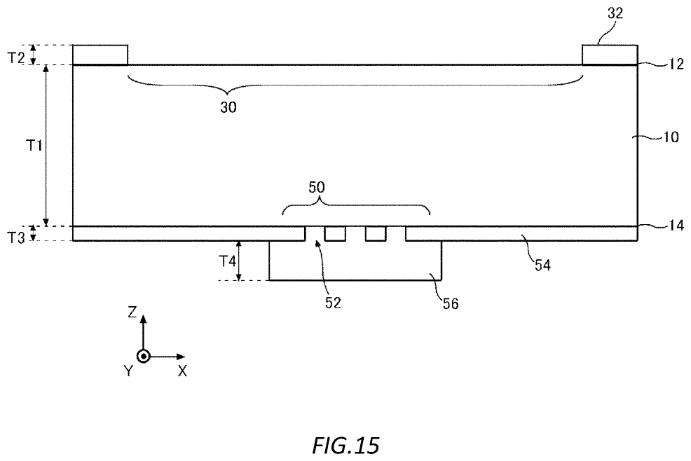

FIG. 15 shows a film thickness of each member. FIG. 15 shows the thickness T1 of the semiconductor substrate 10, a film thickness T2 of the resist 32, a film thickness T3 of the film 54, and a film thickness T4 of the cover portion 56. As one example, the thickness T1 of the semiconductor substrate 10 is 60 μm or more and 380 μm or less. The thickness T1 may be determined according to a breakdown voltage which the semiconductor apparatus should have.

As one example, the film thickness T2 of the resist 32 is 1 μm or more and 6 μm or less. In other words, a height of the upper surface mark 30 is 1 μm or more and 6 μm or less. As one example, the film thickness T3 of the film 54 is 0.3 μm or more and 1.2 μm or less. In other words, a height of the lower surface mark 50 is 0.3 μm or more and 1.2 μm or less. As one example, the film thickness T4 of the cover portion 56 is 0.5 μm or more and 6 μm or less. The film thickness T4 may be a thickness of a portion formed below the film 54. In addition, if a groove is formed in the semiconductor substrate 10 itself to form any mark, a depth of that groove may be 5 μm or more and 6 μm or less.

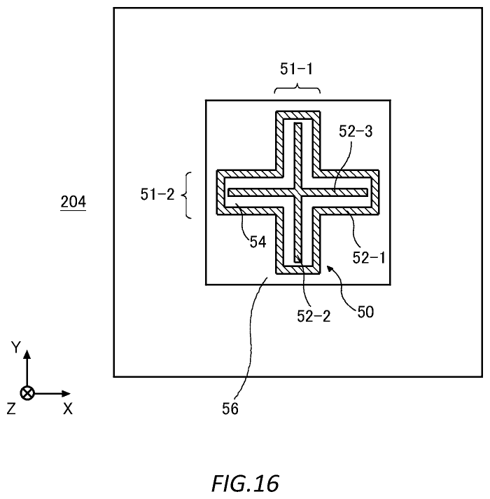

FIG. 16 shows another structural example of the lower surface mark 50. The lower surface mark 50 in the present example is different from the lower surface mark 50 in FIG. 1 to FIG. 15, in a structure of the groove portion 52. Other structures are similar to those of the lower surface mark 50 in any of the examples described in FIG. 1 to FIG. 15.

The lower surface mark 50 in the present example has a groove portion 52-1, a groove portion 52-2, and a groove portion 52-3. The groove portion 52-1 is arranged along a contour of two straight portions 51. The groove portion 52-1 in the present example is arranged along a contour of a shape obtained by crossing a rectangular shape whose longitudinal length is in an X axis direction and a rectangular shape whose longitudinal length is in a Y axis direction.

The groove portion 52-2 and the groove portion 52-3 are arranged in a region enclosed by the groove portion 52-1. The groove portion 52-2 in the present example extends in the Y axis direction, and the groove portion 52-3 extends in the X axis direction. The groove portion 52-2 and the groove portion 52-3 cross each other at their central portions.

In the examples of FIG. 1 to FIG. 15, both ends of the groove portion 52-2 in the Y axis direction and both ends of the groove portion 52-3 in the X axis direction are connected to the groove portion 52-1. The both ends of the groove portion 52-2 in the Y axis direction and the both ends of the groove portion 52-3 in the X axis direction in the present example are separated from the groove portion 52-1. The film 54 remains between the groove portion 52-2 and the groove portion 52-3, and the groove portion 52-1. According to the present example, a crossing portion between the groove portions 52 can be reduced.

If the groove portion 52 is formed through etching or the like using a resist, the resist is shaped according to a pattern of the groove portion 52 to be formed. If there is the crossing portion between the groove portions 52, the resist is divided into small regions, and the resist is likely to be stripped. In the present example, since the crossing portion of the groove portion 52 can be reduced, the stripping of the resist can be suppressed to accurately form the groove portion 52.

If the groove portion 52 is formed through etching or the like, a width of the groove portion 52 may be larger in the crossing portion between the groove portions 52 than in other portions. If a material such as polysilicon is embedded in the groove portion 52, there is a case where that material cannot be sufficiently embedded in a portion with a large width of the groove portion 52. If there is a portion where that material is not sufficiently embedded in the groove portion 52, the resist or the like may enter that portion, and the resist or the like may remain there. In addition, that portion can become a source of a foreign substance. According to the present example, since the crossing portion of the groove portion 52 can be reduced, the groove portion 52 can be accurately embedded.

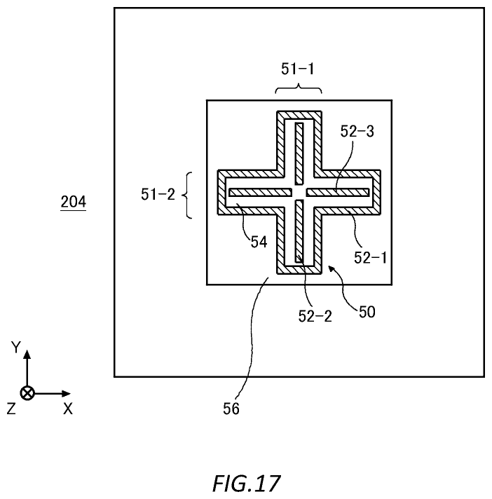

FIG. 17 shows another structural example of the lower surface mark 50. The lower surface mark 50 in the present example is different from that in the example of FIG. 16, in structures of the groove portion 52-2 and the groove portion 52-3. Other structures are similar to those in the example of FIG. 16.

The groove portion 52-2 in the present example is separated into two by the film 54 arranged in a central portion in a Y axis direction. The groove portion 52-3 is separated into two by the film 54 arranged in a central portion in an X axis direction. The groove portion 52-2 and the groove portion 52-3 are also separated from each other by the film 54 arranged in a crossing portion. According to the present example, the crossing portion of the groove portion 52 can be further reduced.

While the present invention has been described by using the embodiments, the technical scope of the present invention is not limited to the scope of the above described embodiments. It is apparent to persons skilled in the art that various alterations or improvements can be added to the above described embodiments. It is also apparent from the scope of the claims that the embodiments added with such alterations or improvements can be included in the technical scope of the present invention.

### EXPLANATION OF REFERENCES

10: semiconductor substrate, 12: upper surface; 14: lower surface; 20: scribe line; 22: semiconductor chip; 30: upper surface mark; 32: resist; 50: lower surface mark; 51: straight portion; 52: groove portion; 54: film; 56: cover portion; 130: upper surface mark; 132: groove portion; 200: image capturing unit; 202, 206, 212, 216: upper surface image; and 204, 208, 214, 218: lower surface image.

What is claimed is:

1. A manufacturing method of a semiconductor apparatus, comprising:
forming a mark by forming an upper surface mark on an upper surface of a semiconductor substrate and a lower surface mark on a lower surface of the semiconductor substrate;
detecting a position by detecting positional deviation of the upper surface mark and the lower surface mark, by acquiring an upper surface image obtained by observing the upper surface mark from above the upper surface of the semiconductor substrate and a lower surface image obtained by observing the lower surface mark through the semiconductor substrate from above the upper surface of the semiconductor substrate; and
forming an element by forming a semiconductor element in the semiconductor substrate, wherein
in a top view in which the upper surface mark and the lower surface mark are projected onto a plane parallel to the upper surface, one of the upper surface mark and the lower surface mark is larger than an other, and the one entirely covers the other.

2. The manufacturing method of a semiconductor apparatus according to claim 1, wherein
in the forming the mark, a cover portion for covering the lower surface mark is formed of a material having a reflectance rate higher than the lower surface mark.

3. The manufacturing method of a semiconductor apparatus according to claim 2, wherein
in the top view, the upper surface mark is larger than the lower surface mark.

4. The manufacturing method of a semiconductor apparatus according to claim 3, wherein
in the top view, the cover portion is larger than the lower surface mark and is smaller than the upper surface mark.

5. The manufacturing method of a semiconductor apparatus according to claim 4, wherein
in the top view, a distance between an end portion of the cover portion and an end portion of the lower surface mark is smaller than a distance between the end portion of the cover portion and an end portion of the upper surface mark.

6. The manufacturing method of a semiconductor apparatus according to claim 1, wherein
in the top view, the lower surface mark is larger than the upper surface mark.

7. The manufacturing method of a semiconductor apparatus according to claim 1, wherein
in the top view, a distance between an end portion of the lower surface mark and an end portion of the upper surface mark is 20 μm or more.

8. The manufacturing method of a semiconductor apparatus according to claim 1, wherein
in the detecting the position, a wavelength of a light to be irradiated to the semiconductor substrate in a case where the upper surface image is acquired is a same as a wavelength of a light irradiated to the semiconductor substrate in a case where the lower surface image is acquired.

9. The manufacturing method of a semiconductor apparatus according to claim 1, wherein
the upper surface mark is a concave portion arranged on the upper surface of the semiconductor substrate.

10. The manufacturing method of a semiconductor apparatus according to claim 1, wherein
the upper surface mark is a convex portion arranged on the upper surface of the semiconductor substrate.

11. The manufacturing method of a semiconductor apparatus according to claim 10, wherein
in the top view, a region provided with no concave or convex is arranged over a range of at least 20 μm toward an outside from an end portion of the upper surface mark.

12. The manufacturing method of a semiconductor apparatus according to claim 9, wherein
the lower surface mark has two or more straight portions with their respective longitudinal directions crossing each other, in the top view.

13. The manufacturing method of a semiconductor apparatus according to claim 2, wherein
the upper surface mark is a concave portion arranged on the upper surface of the semiconductor substrate.

14. The manufacturing method of a semiconductor apparatus according to claim 3, wherein
the upper surface mark is a concave portion arranged on the upper surface of the semiconductor substrate.

15. The manufacturing method of a semiconductor apparatus according to claim 4, wherein
the upper surface mark is a concave portion arranged on the upper surface of the semiconductor substrate.

16. The manufacturing method of a semiconductor apparatus according to claim 5, wherein
the upper surface mark is a concave portion arranged on the upper surface of the semiconductor substrate.

17. The manufacturing method of a semiconductor apparatus according to claim 6, wherein
the upper surface mark is a concave portion arranged on the upper surface of the semiconductor substrate.

18. The manufacturing method of a semiconductor apparatus according to claim 7, wherein
the upper surface mark is a concave portion arranged on the upper surface of the semiconductor substrate.

19. The manufacturing method of a semiconductor apparatus according to claim 8, wherein
the upper surface mark is a concave portion arranged on the upper surface of the semiconductor substrate.

20. The manufacturing method of a semiconductor apparatus according to claim 2, wherein
the upper surface mark is a convex portion arranged on the upper surface of the semiconductor substrate.
